(19) United States
(12) Patent Application Publication
(10) Pub. No.: US 2024/0052952 A1
(43) Pub. Date: Feb. 15, 2024

(54) CABLE ANCHOR SYSTEM

(71) Applicant: CommScope Technologies LLC, Hickory, NC (US)

(72) Inventors: Cyle D. PETERSEN, Belle Plaine, MN (US); Ryan D. WILLIS, Minneapolis, MN (US); James J. SOLHEID, Minneapolis, MN (US); David Jan Irma VAN BAELEN, Winksele (BE); Matthew J. HOLMBERG, Le Center, MN (US)

(21) Appl. No.: 18/492,274

(22) Filed: Oct. 23, 2023

Related U.S. Application Data
(63) Continuation of application No. PCT/US2022/025731, filed on Apr. 21, 2022.
(60) Provisional application No. 63/178,944, filed on Apr. 23, 2021.

(51) Int. Cl. F16L 3/22; F16L 3/06; H05K 7/14; H04Q 1/06

(52) U.S. Cl. CPC F16L 3/221; F16L 3/06; H05K 7/14; H04Q 1/06; H02G 3/32

(57) ABSTRACT

A cable anchor includes an anchor mounting structure and a cable mounting structure. The anchor mounting structure can releasably mount to a support plate along either of two paths. The cable mounting structure secures one or more cables to the cable anchor. Some example cable mounting structures are configured to receive wrap-style fasteners to hold cables. Other example cable mounting structures include fanout bodies configured to receive epoxy. Other example cable mounting structures include cavities configured to engage overmolded retention features of a cable.

### CROSS-REFERENCE TO RELATED APPLICATIONS

This application is a Continuation of International Patent Application No. PCT/US2022/025731, filed on Apr. 21, 2022, which claims the benefit of U.S. Patent Application Ser. No. 63/178,944, filed on Apr. 23, 2021, the disclosures of which are incorporated herein by reference in their entireties. To the extent appropriate, a claim of priority is made to each of the above disclosed applications.

### BACKGROUND

The installation of telecommunications modules in a racking system has previous involved mounting the modules to one or more chassis, which are mounted to a rack. Cables can be routed along the rack (e.g., from overhead troughs or below-ground ducts), to the chassis, and then to the modules.

In some examples, the cables can be secured directly to the chassis or rack using wrap-style fasteners (e.g., cable ties, hook-and-loop fasteners, etc.). However, any changes (e.g., moving the cables, adding another cable, replacing one of the cable, etc.) may require unwrapping or breaking of the wrap-style fastener. Further, a user may need to thread a wrap-style fastener (e.g., a new fastener) through the mounting structure on the chassis or rack after the mounting structure is surrounded and/or covered by other anchored cables.

In other examples, the cables can be secured to cable anchors (e.g., cable clamps), which are removably mounted to the chassis or rack. In some cases, the user is supplied with multiple sizes and/or styles of clamps, gaskets, etc. to accommodate cables of various cross-dimensions (e.g., diameters) and/or shapes (e.g., round, flat, etc.) that the user may wish to secure to the chassis or rack. The multitude of parts can be confusing for customers and expensive to manufacture and supply.

Improvements are desired.

### SUMMARY

Aspects of the present disclosure are directed to a cable anchor to which one or more cables (e.g., optical cables, electrical cables, hybrid cables, etc.) can mount.

In accordance with certain aspects of the disclosure, the cable anchor is removably coupled to a support plate to attach the one or more cables to the support plate. In certain implementations, the cable anchor slides onto the support plate and latches in place.

In certain implementations, the support plate defines a slot having an enlarged section. The cable anchor includes a set of rails extending outwardly wider than a non-enlarged section of the slot. The set of rails fits through the enlarged section so that the set of rails can pass through the support plate at the enlarged section.

In certain implementations, the cable anchor is configured to mount to and release from the support plate along two different paths to accommodate a surrounding environment. In certain examples, the support plate defines two enlarged sections spaced from each other along the slot. The cable anchor includes two sets of rails that are spaced from each other along a length of the cable anchor.

To mount the cable anchor to the support plate along a first path, the cable anchor is slid relative to the support plate so that at least portions of both sets of rails pass through one of the enlarged sections and neither of the sets of rails pass through the other of the enlarged sections. To mount the cable anchor to the support plate along a second path, the cable anchor is slid relative to the support plate so that the first set of rails passes through one of the enlarged sections, the cable anchor is tilted relative to the support plate to align the second set of rails with the other enlarged section, and the cable anchor is slid relative to the support plate so that at least a portion of the second set of rails passes through the other enlarged section.

The cable anchor can be removed from the support plate along either the first path or the second path at the discretion of the user.

In some implementations, the cable anchor receives a retention member carried by the cable. In certain examples, the retention member is overmolded or otherwise axially fixed onto a jacket of the cable. In certain examples, the retention member is offset from a cable transition region at which the cable jacket is terminated and one or more media segments extend beyond the cable jacket.

In other implementations, the cable anchor receives a cable transition region of the cable at which one or more media segments extend past a terminated end of the cable jacket. In certain examples, the jacket, strength members, and/or media segments of the cable are affixed (e.g., epoxied) within a body of the cable anchor.

In some implementations, the cable anchor is configured to axially retain multiple cables. For example, a group of cables can be attached to the cable anchor using a wrap-style fastener (e.g., a cable-tie, a hook-and-loop fastener, etc.). In certain examples, the cable anchor defines one or more channels through which the wrap-style fastener may extend.

In other implementations, two or more cable anchors can stack together. Accordingly, even if each cable anchor holds only one cable, multiple cables can still be accommodated at the same space on the support plate. In certain implementations, a first cable anchor has a first side defining mounting structure to mate with the support plate and a second side defining receiving structure configured to mate with the mounting structure. Accordingly, a second cable anchor can mount to the second side of the first cable anchor. In certain implementations, the receiving structure includes a plurality of pairs of tabs that cooperate to define a channel.

A variety of additional inventive aspects will be set forth in the description that follows. The inventive aspects can relate to individual features and to combinations of features. It is to be understood that both the forgoing general description and the following detailed description are exemplary and explanatory only and are not restrictive of the broad inventive concepts upon which the embodiments disclosed herein are based.

### BRIEF DESCRIPTION OF THE DRAWINGS

The accompanying drawings, which are incorporated in and constitute a part of the description, illustrate several aspects of the present disclosure. A brief description of the drawings is as follows:

FIG. 1 is a rear perspective view of an example management shelf disposed at a rear of a chassis of a panel system, the management shelf including multiple cable anchor stations;

FIG. 2 is a top perspective view of an example support plate configured to be disposed at a management shelf;

FIG. 3 is a bottom perspective view of the support plate of FIG. 2;

FIG. 4 is a side elevational view of the support plate of FIG. 2;

FIG. 5 is a top plan view of the support plate of FIG. 2;

FIG. 6 is a top perspective view of a first example type of cable anchor configured in accordance with the principles of the present disclosure;

FIG. 7 is a bottom perspective view of the cable anchor of FIG. 6;

FIG. 8 is a side elevational view of the cable anchor of FIG. 6;

FIG. 9 is a top plan view of the cable anchor of FIG. 6;

FIG. 10 is a top plan view of the cable anchor of FIG. 6;

FIG. 11 is a top perspective view of the support plate of FIG. 2 with another example cable anchor aligned with an anchor station of the support plate;

FIG. 12 is a bottom perspective view of the support plate and cable anchor of FIG. 11;

FIG. 13 is a top perspective view of the support plate and cable anchor of FIG. 11 with the cable anchor slid partially along the cable anchor station;

FIG. 14 is a bottom perspective view of the support plate and cable anchor of FIG. 13;

FIG. 15 is a top perspective view of the support plate and cable anchor of FIG. 11 with the cable anchor fully mounted at the cable anchor station;

FIG. 16 is a bottom perspective view of the support plate and cable anchor of FIG. 15;

FIG. 17 is a top perspective view of the cable anchor of FIG. 11 with the first set of rails aligned with the second enlarged section of the slot of a cable anchor location of the support plate;

FIG. 18 shows two cable ties mounted to the cable anchor of FIG. 6, which is mounted to the support plate of FIG. 2; no cables are shown in FIG. 18 for ease in viewing the interaction between the cable ties and the cable anchor;

FIG. 19 shows a plurality of cable anchors of FIG. 6 mounted to the support plate of FIG. 2, each of the cable anchors holding a plurality of cables using cable ties;

FIG. 20 shows different numbers and sizes of cables mounted to the first type of cable anchors;

FIG. 21 is a top perspective view of a second example type of cable anchor configured in accordance with the principles of the present disclosure;

FIG. 22 shows a second housing piece exploded away from a first housing piece of the cable anchor of FIG. 21;

FIG. 23 is a bottom perspective view of the cable anchor of FIG. 21;

FIG. 24 shows multiple ones of the cable anchor of FIG. 21 mounted to a support plate including a stacked arrangement of the cable anchors;

FIG. 25 shows an upper cable anchor positioned to be mounted to a lower cable anchor along a first path;

FIG. 26 shows the upper cable anchor of FIG. 25 positioned to be mounted to the lower cable anchor along a second path;

FIG. 27 is a top perspective view of a third example type of cable anchor configured in accordance with the principles of the present disclosure;

FIG. 28 is an exploded view of the third type of cable anchor of in FIG. 27;

FIG. 29 is a bottom perspective view of the cable anchor of FIG. 27;

FIG. 30 is a stacked arrangement of the cable anchors of FIG. 27;

FIG. 31 is a perspective view of multiple ones of the cable anchor of FIG. 27 mounted to a support plate including stacked arrangement of the cable anchors;

FIG. 32 is a perspective view of a cable management shelf including a blocking arrangement disposed at a cable routing entrance;

FIG. 33 is a bottom perspective view of the blocking arrangement shown mounted to a plurality of cable anchors; and

FIG. 34 is a top perspective view of the blocking arrangement of FIG. 33.

### DETAILED DESCRIPTION

Reference will now be made in detail to exemplary aspects of the present disclosure that are illustrated in the accompanying drawings. Wherever possible, the same reference numbers will be used throughout the drawings to refer to the same or like parts.

The present disclosure is directed to a cable anchor to which one or more cables (e.g., optical cables, electrical cables, hybrid cables, etc.) can mount. The cable anchor is adapted to receive a variety of different types of cables. In some implementations, the cable anchor is integral with a furcation body at which a ribbon cable is transitioned to multiple furcation cables. In other implementations, the cable anchor is configured to axially and rotationally attach to an outer jacket of the cable. In still other implementations, the one or more cables are attached to the cable anchor with a wrap-style fastener (e.g., a cable tie, a hook-and-loop strip, etc.).

Each cable anchor is mountable at a cable anchor station of a support plate. In some implementations, the cable anchor receives a single cable. In some examples, the single cable includes a single bundle of fibers within an outer jacket. In other examples, the single cable includes a plurality of fiber bundles (e.g., sub-cables) within the outer jacket. In certain examples, the cable anchors are stackable so that multiple cables can be received at a common cable anchor station. In other implementations, the cable anchor receives a bundle of different cables to mount multiple cables at a common cable anchor station. In certain examples, cables can be added to and/or removed from the bundle.

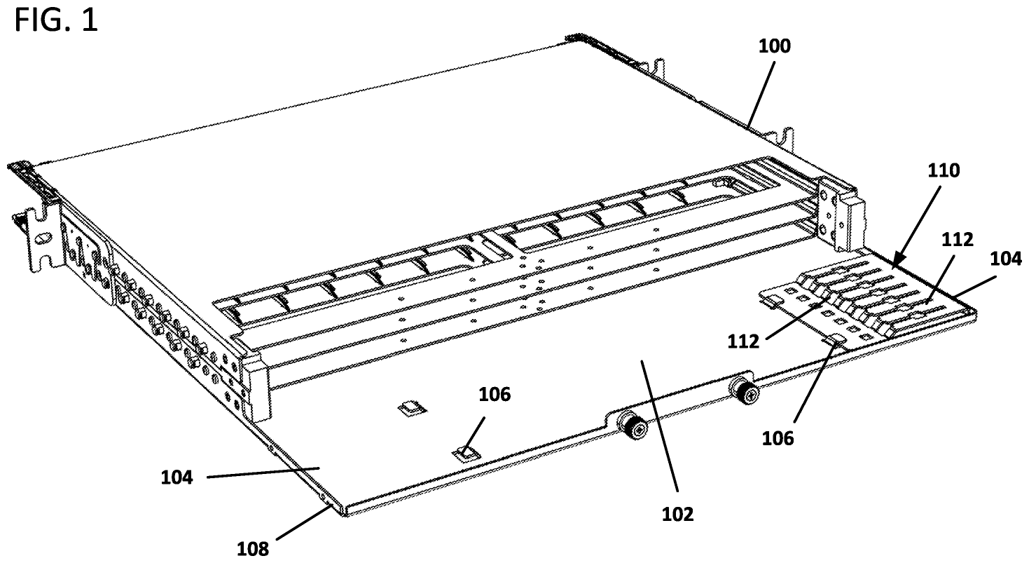

Referring to FIG. 1, a support plate 110 defining one or more cable anchor stations 112 can be mounted at a chassis 100 to secure cables 180 routed to the chassis 100. In the example shown, the support plate 110 is mounted at a cable management shelf 102 at one end (e.g., the rear) of the chassis 100. In other examples, the support plate 110 can be mounted at a front of the chassis 100, at a side of the chassis 100, at a location spaced from the chassis 100 (e.g., on a bracket mounted to the chassis 100, on a rack to which the chassis 100 is mounted, etc.).

In certain implementations, the support plate 110 is mounted to a cable routing entrance 104 of the management shelf 102. In the example shown, the management shelf 102 defines a first cable routing entrance 104 at a first side of the management shelf 102 and a second cable routing entrance 104 at an opposite second side of the management shelf 102. In other examples, the cable routing entrance may be disposed at a central region of the cable management shelf 102. In still other examples, the support plate 110 is offset from the cable routing entrance 104.

In some implementations, the support plate 110 is removably mounted at the cable management shelf 102. In the example shown, a first end of the plate 110 is slid beneath one or more tabs 106 protruding from the management shelf 102. An opposite second end of support plate 110 is removably secured (e.g., using fasteners) to a wall or flange 108 of the cable management shelf 102. In other examples, the support plate 110 can be latched, friction fit, fully fastened, or otherwise removably mounted to the management shelf 102. In still other examples, the support plate 110 can be integral with the shelf 102, such as being monolithically formed, welded, or otherwise permanently affixed.

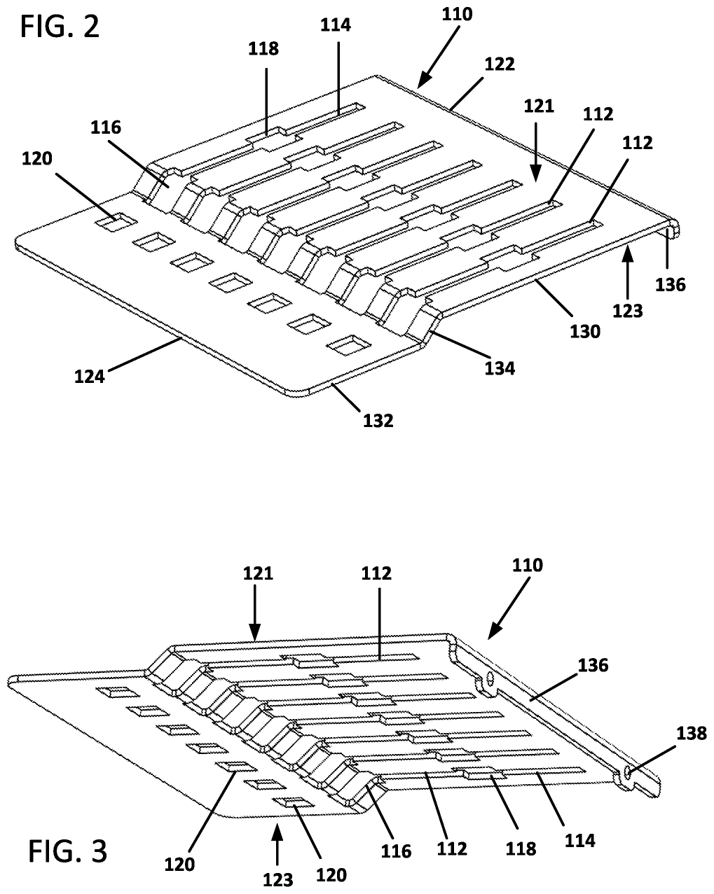

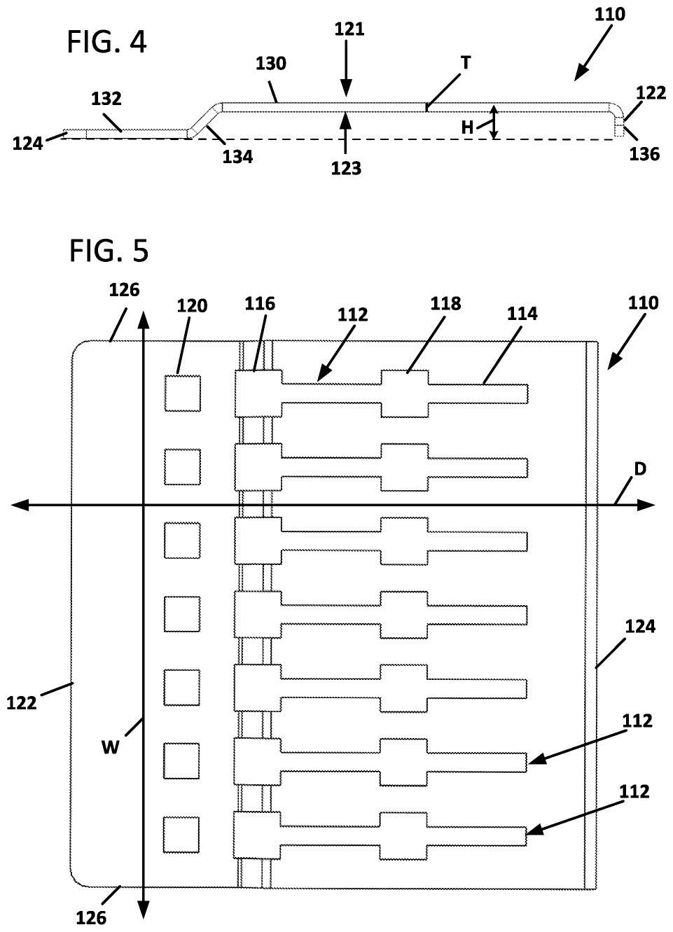

Referring to FIGS. 2-5, the support plate 110 defines one or more cable anchor mounting stations 112. The support plate 110 extends along a depth D between a first end 122 and a second end 124 and along a width W between a first side 126 and a second side 128 (see FIG. 5). The support plate 110 also extends along a thickness T between a top 121 and a bottom 123 (see FIG. 4). In certain implementations, each cable anchor mounting station 112 has a common configuration.

In certain implementations, each cable anchor mounting station 112 is elongate along the depth D of the support plate 110. In certain implementations, the cable anchor mounting stations 112 are arranged in a row along the width W of the support plate 110. In some examples, the cable anchor mounting stations 112 are aligned along the width W of the support plate 110. In other examples, the cable anchor mounting stations 112 are offset along the depth D of the support plate 110 relative to each other.

In certain implementations, each cable anchor mounting station 112 includes a slot 114 and an aperture 120 each extending through the thickness T of the support plate 110. The aperture 120 is spaced from, but aligns with the slot 114 along the depth D of the support plate 110. Each slot 114 is elongate along the depth D of the support plate 110. In some examples, the slot 114 extends between two closed ends so that the slot 114 terminates before reaching either of the ends 122, 124 of the support plate 110. In other examples, the slot 114 may extend between a closed end and an open end (i.e., one end may reach one of the ends 122, 124 of the support plate 110). In still other examples, the slot 114 may be open at both ends and the aperture 120 may be defined by a separate plate.

In certain implementations, the slot 114 of each cable anchor mounting station 112 includes a first enlarged section 116 and a second enlarged section 118 spaced apart along the depth D of the support plate 110. In certain examples, the first enlarged section 116 forms a first end of the slot 114 adjacent the aperture 120. In certain examples, the second enlarged section 118 is disposed at an intermediate point between the first enlarged section 116 and a second end of the slot 114. In the example shown, the second enlarged section 118 is centrally disposed between the first enlarged section 116 and a second end of the slot 114.

In some implementations, the support plate 110 is flat. In other implementations, the support plate 110 includes a first region 130 defining the first end 122, a second region 132 defining the second end 124, and a transition region 134 extending between the first and second regions 130, 132 (e.g. see FIG. 1). The transition region 134 is contoured so that the second region 132 is raised along a height H relative to the first region 130 (see FIG. 4). The height H extends in parallel with the thickness T of the support plate 110 (see FIG. 4).

In certain implementations, the first enlarged section 116 is disposed at the first region 130, the second enlarged section 118 is disposed at the transition region 134, and the aperture 120 is disposed at the second region 132. In certain examples, the first and second regions 130, 132 are parallel to each other. In certain examples, the second enlarged section 118 is angled along the height H relative to the first enlarged section 116.

In certain examples, the support plate 110 includes a flange 136 that extends downwardly along the height H from the first end 122 of the support plate 110. The flange 136 may define one or more fastener apertures 138 (see FIG. 3) through which fasteners (e.g., screws, pushpins, etc.) may extend to attach the support plate 110 to a surface (e.g., a wall of flange of the cable management shelf 102 of the chassis 100 of FIG. 1). In the example shown, the flange 136 extends downwardly so that a bottom of the flange 136 is about level with a bottom of the second region 132.

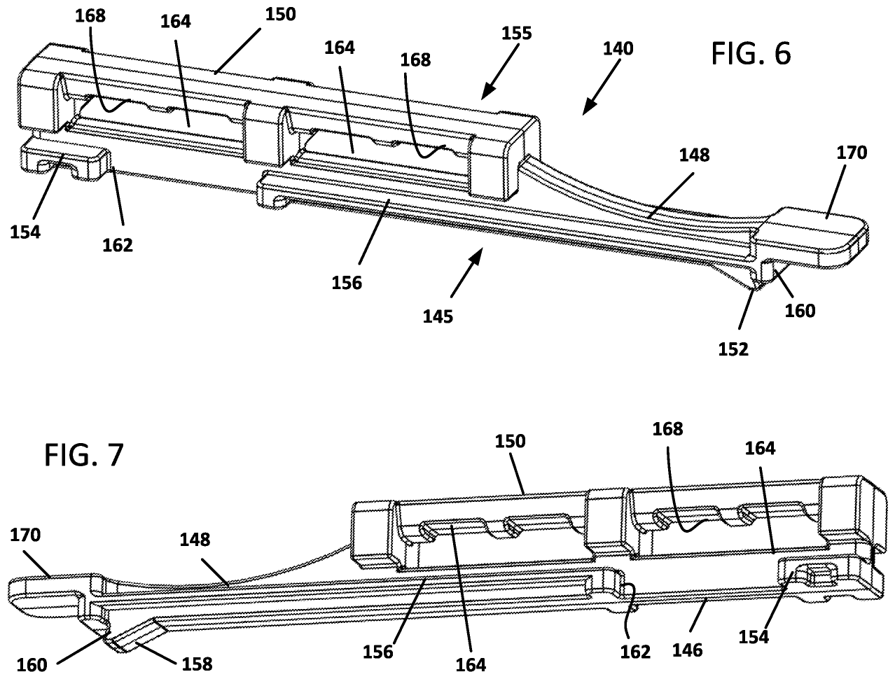

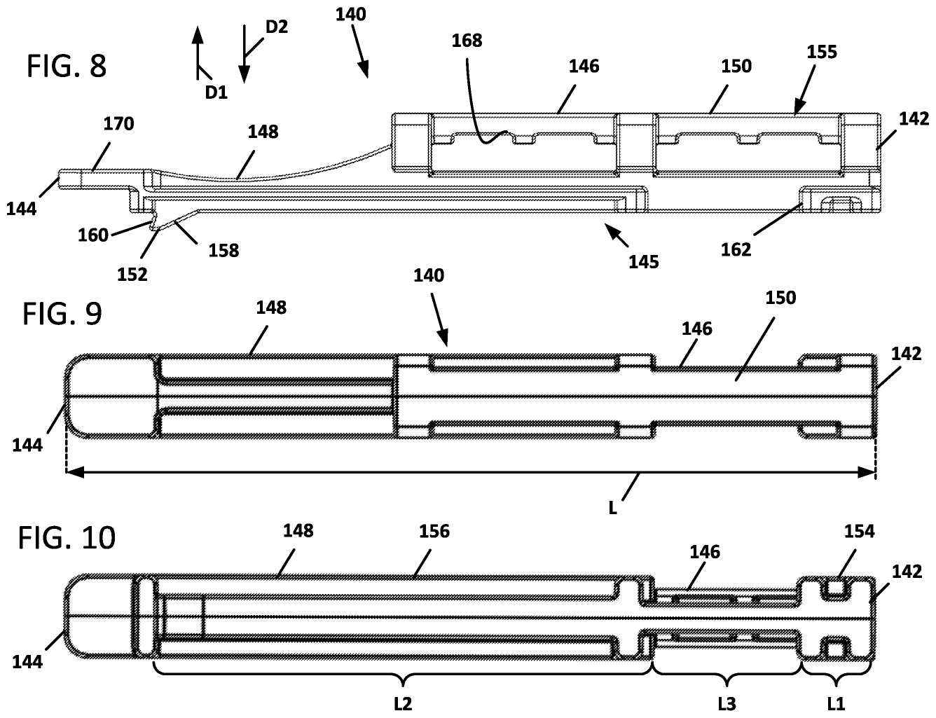

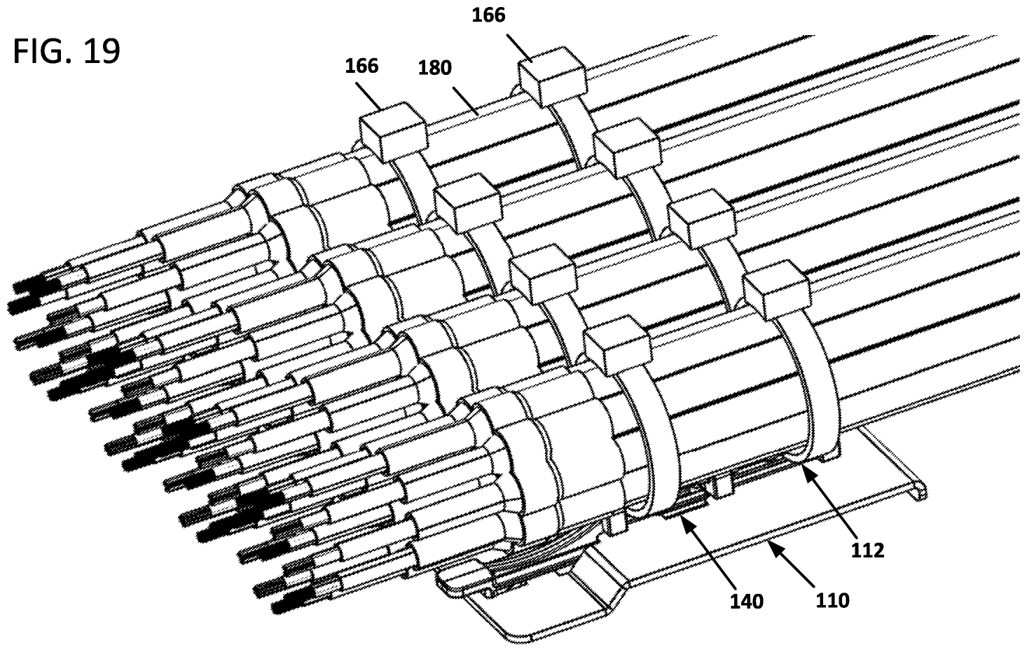

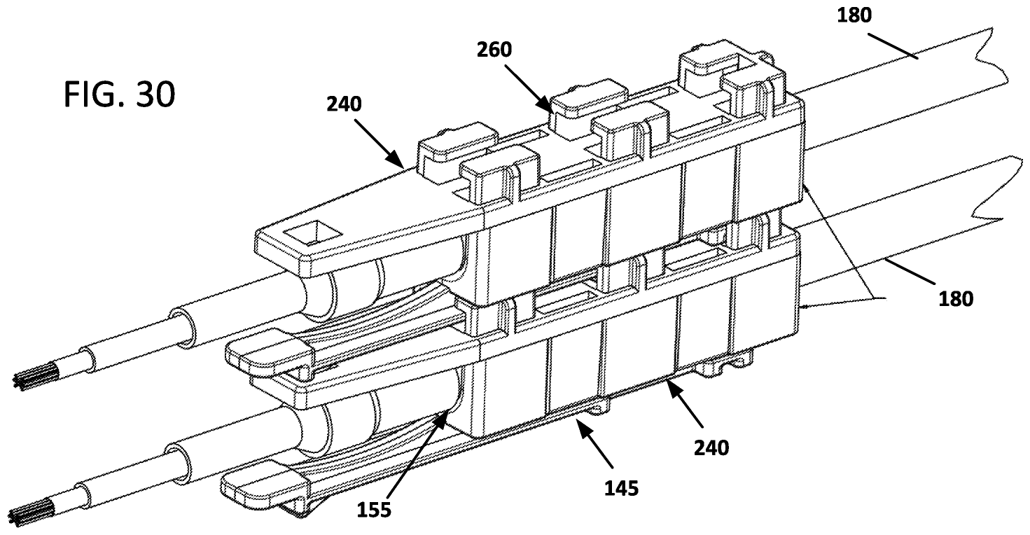

Referring to FIGS. 6-31, a cable anchor 140, 190, 240 includes an anchor mounting structure 145 and a cable mounting structure 155. The cable anchor 140, 190, 240 has a length L (FIG. 8) that extends between opposite first and second ends 142, 144 of the cable anchor 140, 190, 240. The cable anchor 140, 190, 240 including a base 146 that defines the cable mounting structure and an arm 148 extending outwardly from the base 146. The base 146 defines a support surface 150 facing in a first direction D1 (see FIG. 8). The arm 148 defines the second end of the cable anchor 140.

The base 146 and the arm 148 cooperate to define the anchor mounting structure 145. The arm 148 carries a latch member 152 extending in a second direction D2 opposite the first direction D1. In certain implementations, the arm 148 is deflectable relative to the base 146. The cable anchor 140, 190, 240 includes a first set of guide rails 154 at opposite sides of the base 146 of the cable anchor 140. The first set of guide rails 154 extend along a first portion L1 of the length L of the cable anchor 140, 190, 240. A second set of guide rails 156 extend along a second portion L2 of the length L of the cable anchor 140, 190, 240 at opposite sides of the cable anchor 140. The second set of rails 156 extend along both the base 146 and the arm 148. The second set of guide rails 156 are spaced from the first set of guide rails 154 along a gap 162 extending along a third portion L3 of the length L of the cable anchor 140.

The guide rails 156 of the second set are longer than the guide rails 154 of the first set. In certain implementations, the rails 156 of the second set are at least twice as long as the rails 154 of the first set. In certain examples, the rails 156 of the second set are at least three times as long as the rails 154 of the first set. In certain examples, the rails 156 of the second set are at least five times as long as the rails 154 of the first set. In certain implementations, the third portion L3 of the length L is larger than the first portion L1 of the length L and smaller than the second portion L2 of the length L.

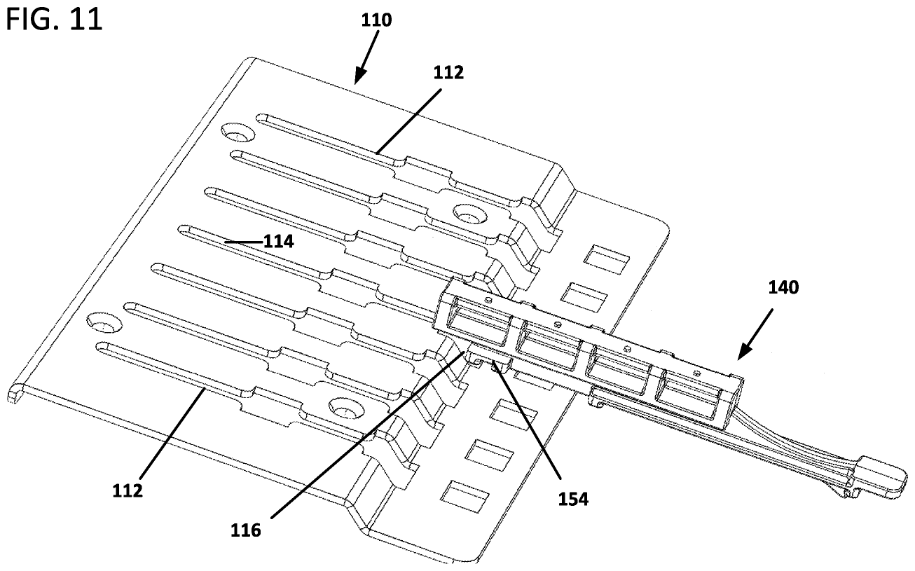

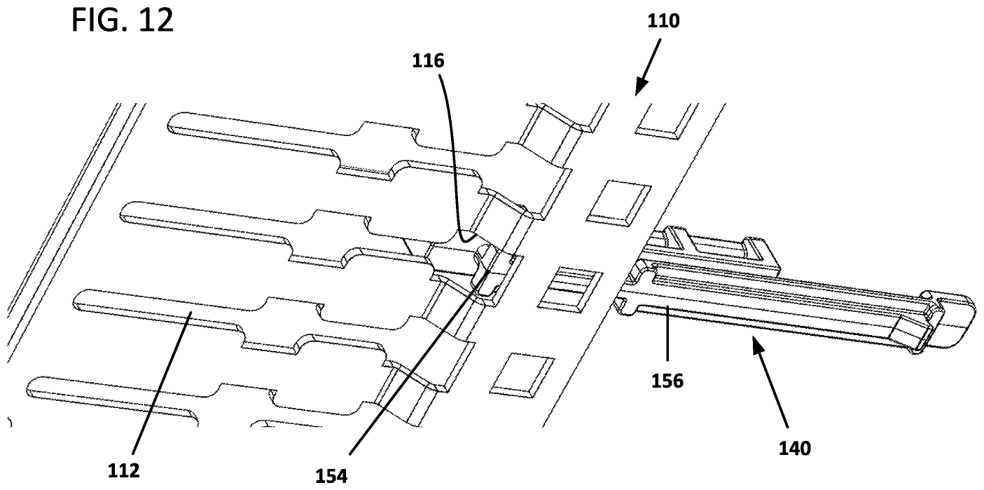

Referring to FIGS. 11-17, the cable anchor 140, 190, 240 is configured to slide onto the support plate 110 and latch in place. In some implementations, the cable anchor 140, 190, 240 can be mounted to the support plate 110 along either of two different paths. FIGS. 11-16 show the cable anchor 140 being mounted along a first path. As shown in FIGS. 11 and 12, the first set of rails 154 of the cable anchor 140, 190, 240 are aligned with the first enlarged section 116 of one of the slots 114 defined in the support plate 110. The length L of the cable anchor aligns along the depth D of the support plate 110.

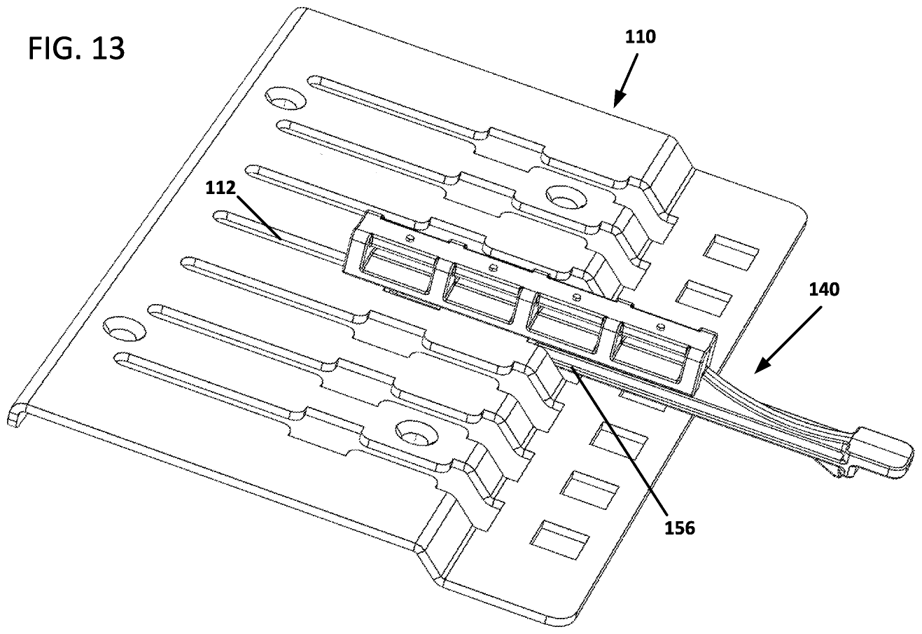

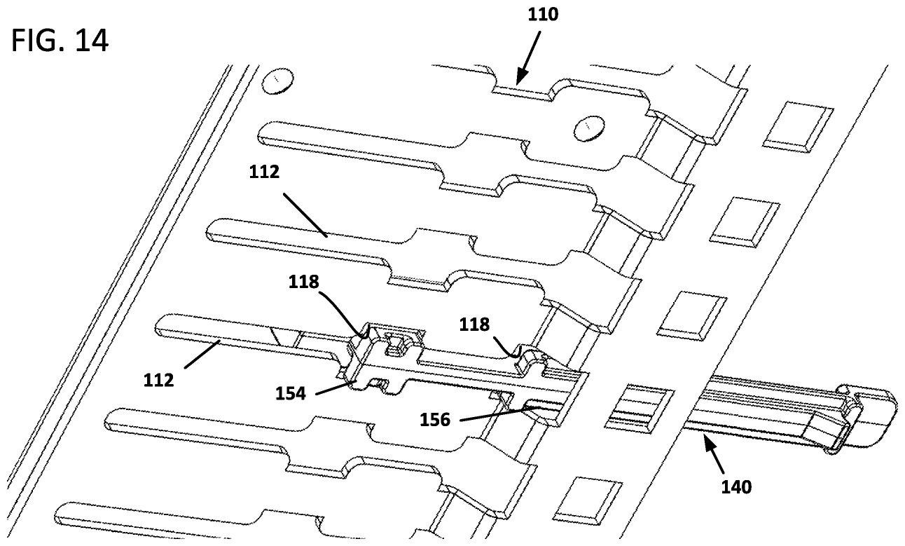

The first set of rails 154 are inserted through the first enlarged section 116 so that the first set of rails 154 pass beneath the support plate 110. The cable anchor 140, 190, 240 is further slid through the first enlarged section 116 as the second set of rails 156 pass through the first enlarged section 116 (e.g., see FIGS. 13 and 14). Interaction between the rails 154, 156 and the bottom 123 of the support plate 110 inhibit upward movement of the cable anchor 140, 190, 240 relative to the support plate 110. Interaction between the base 146 of the cable anchor 140, 190, 240 and the top 121 of the support plate 110 inhibits downward movement of the cable anchor 140, 190, 240 relative to the support plate 110.

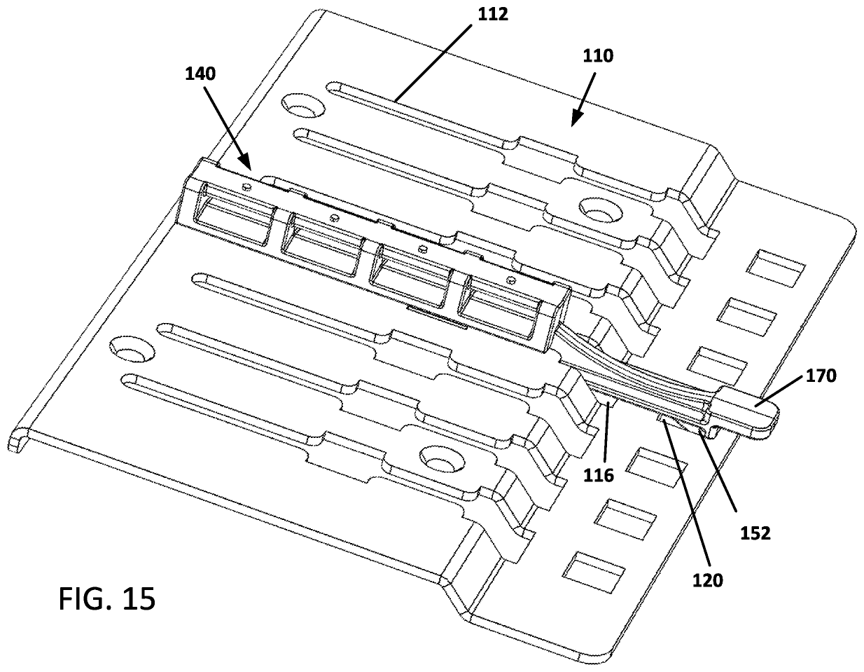

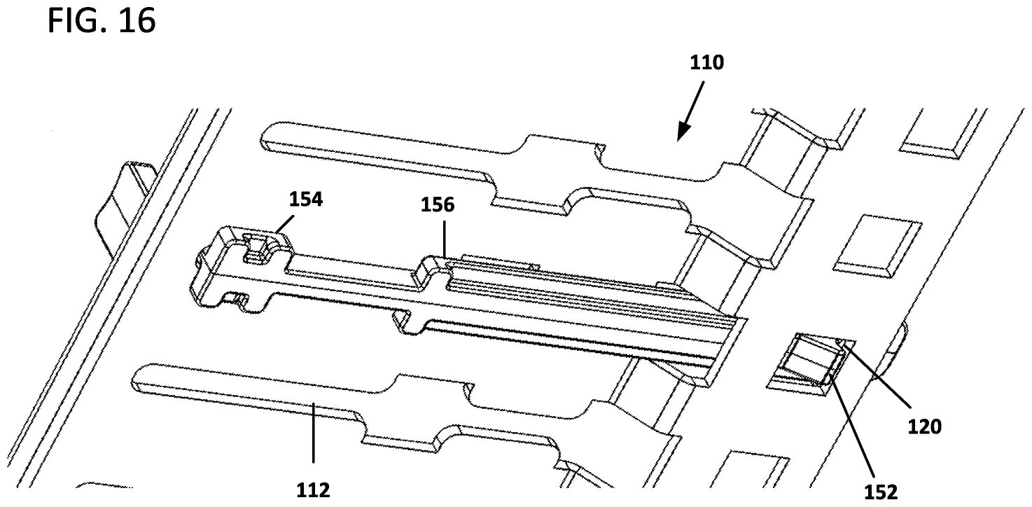

The cable anchor 140, 190, 240 is slid along the slot 114 of the cable anchor station 112 until the latch member 152 aligns with the aperture 120 aligned with the slot 114. Because the latch member 152 is disposed at a distal end of the deflectable arm 148, the latch member 152 removably engages the aperture 120 when aligned (e.g., see FIGS. 15 and 16). In certain examples, the latch member 152 defines a ramp 158 facing partially towards the first end 142 of the cable anchor and a shoulder 160 facing at least partially towards the second end 144. In some examples, the shoulder 160 extends transverse to the arm 148. In other examples, the shoulder 160 is angled relative to the arm 148 at a non-ninety degree angle (e.g., see FIG. 8).

The cable anchor 140, 190, 240 can be released from the support plate 110 along the first path. The latch member 152 is released from the aperture 120 by deflecting the arm 148 relative to the base 146 until the shoulder 160 clears the aperture 120. In certain examples, the arm 148 defines a gripping surface 170 at the distal end by which the arm 148 can be deflected along the first direction D1. The cable anchor 140, 190, 240 can then be slid along the slot 114 until both sets of rails 154, 156 pass through the first enlarged section 116 of the slot 114.

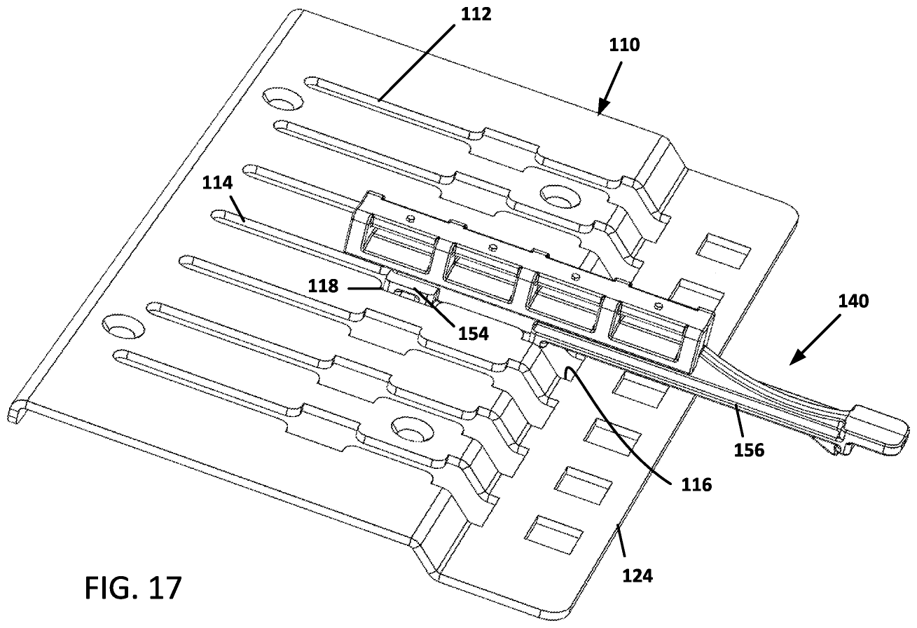

FIG. 17 illustrates a second path by which the cable anchor 140, 190, 240 can be mounted to the support plate 110. When following the second path, the cable anchor 140, 190, 240 is positioned relative to the support plate 110 so that the first rails 154 align with the second enlarged section 118 of the cable anchor slot 114 and the second rails 156 align with the first enlarged section 116 of the cable anchor slot 114. The gap 162 between the first and second rails 154, 156 is about equal to the gap between the first and second enlarged sections 116, 118. Accordingly, the cable anchor 140, 190, 240 can be lowered through the cable anchor slot 114. Once lowered, the cable anchor 140, 190, 240 can be slid along the slot 114 as described above until the latch member 152 engages the aperture 120. Mounting the cable anchor 140, 190, 240 following the second path decreases the distance which the cable anchor 140, 190, 240 initially protrudes beyond the second end 124 of the support plate 110. Decreasing this distance may be useful to avoid interaction with objects (e.g., cables) that would otherwise be in the way.

The cable anchor 140, 190, 240 also can be released from the support plate 110 along the second path. After the latch member 152 is released from the aperture 120 (e.g., via gripping member 170), the cable anchor 140, 190, 240 is slid along the slot until the second set of rails 156 have passed through the first enlarged section 116 and the first set of rails 154 align with the second enlarged section 118. The cable anchor 140, 190, 240 can then be lifted through the slot 114. Removing the cable anchor 140, 190, 240 along the second path decreases the distance the cable anchor 140, 190, 240 protrudes from the support plate 110 during removal, which may facilitate removal in a tightly packed area.

Referring to FIGS. 6-20, the cable mounting structure 155 of a first type of cable anchor 140 is shown. The base 146 of the cable anchor 140 defines one or more passages 164 extending transverse to the length L of the cable anchor 140. Each passage 164 is defined beneath the support surface 150 and above the first and second sets of guide rails 154, 156. In the example depicted in FIGS. 6-10 and 18-19, the base 146 defines two passages 164. In another example depicted in FIGS. 11-17 and 20, the base 146 defines four passages 164.

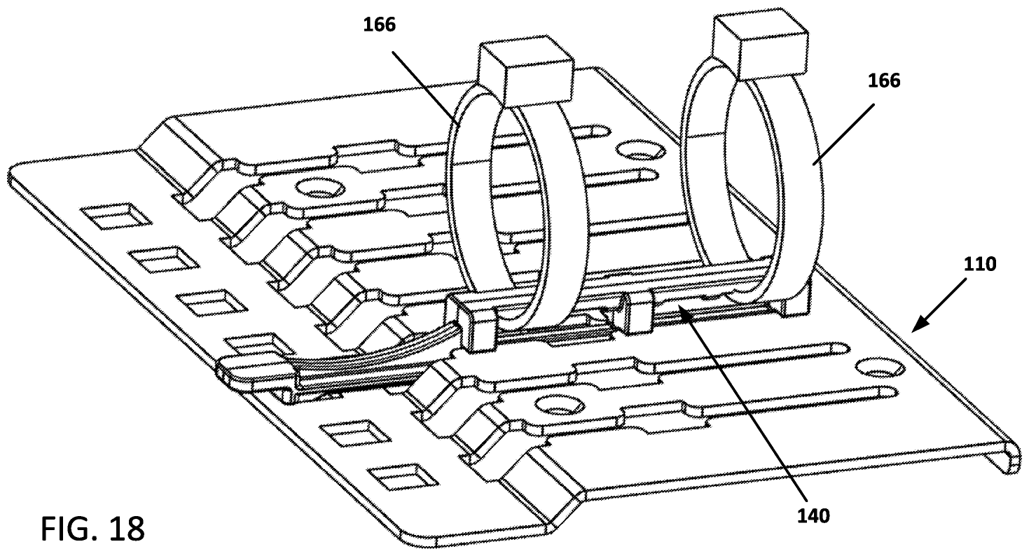

As shown in FIGS. 18-20, a wrap-style fastener 166 may be inserted through one of the passages 164 to hold one or more cables 180 to the support surface 150. In the depicted example, the wrap-style fasteners 166 include cable ties. In other examples, the wrap-style fasteners 166 include fabric hook-and-loop fasteners. The wrap-style fasteners 166 provide flexibility to hold a range of cable sizes and/or number of cables 180.

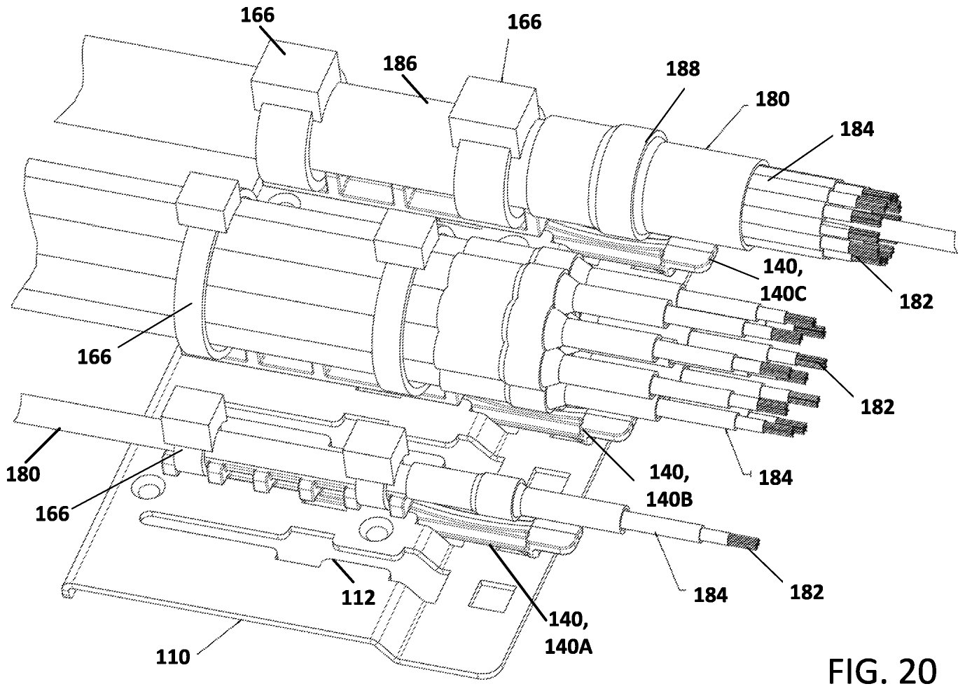

For example, in FIG. 20, a first cable anchor 140A holds a single cable 180 of multiple fibers 182 managed in a single loose tube 184; a second cable anchor 140B holds multiple cables 180 of the type held by the first cable anchor 140A; and a third cable anchor 140C holds a single cable 180 having fibers 182 managed in multiple loose tubes 184 disposed within a cable jacket 186. In certain examples, shape recoverable members (e.g., heat shrink sleeves) are mounted over the cables 180 to transition between the outer jacket 186 and the loose tube(s) 184. In certain examples, the wrap-style fasteners 166 are wound around a jacketed portion of the cables 180.

As shown in FIGS. 6-8, the passages 164 of the cable anchor 140 may be configured to receive any of multiple types of wrap-style fasteners 166. For example, each passage 164 may be sufficiently long to accommodate a wider fabric hook-and-loop style fastener while providing depressions 168 to better secure one or more narrower cable ties within the passage 164 (e.g., see FIG. 18). The depressions 168 also allow multiple cable ties to be secured within a single passage 164. In other examples, the passages 164 may be sized to accommodate the cable ties (e.g., see FIG. 20).

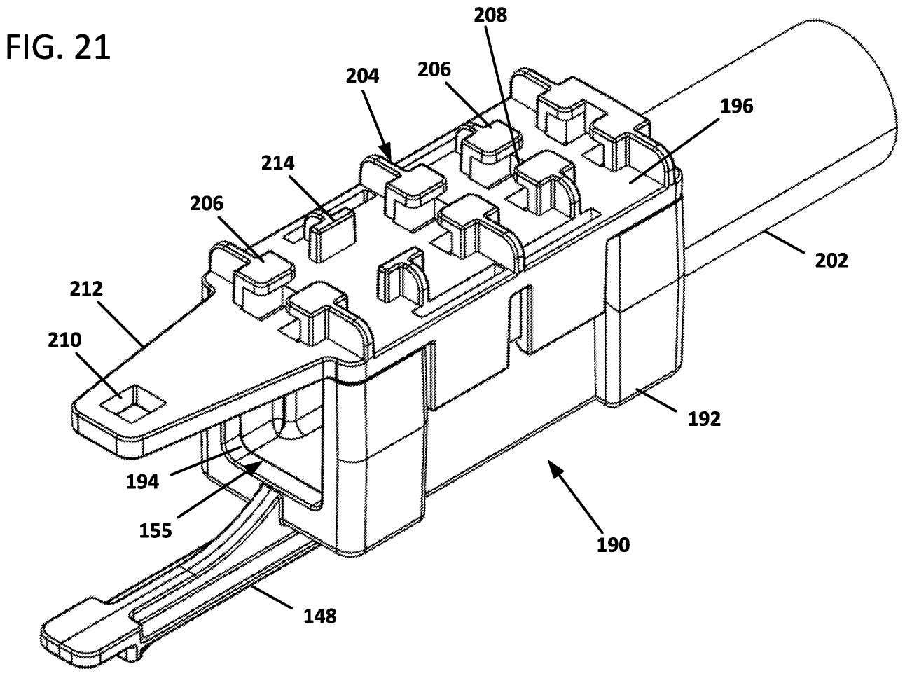

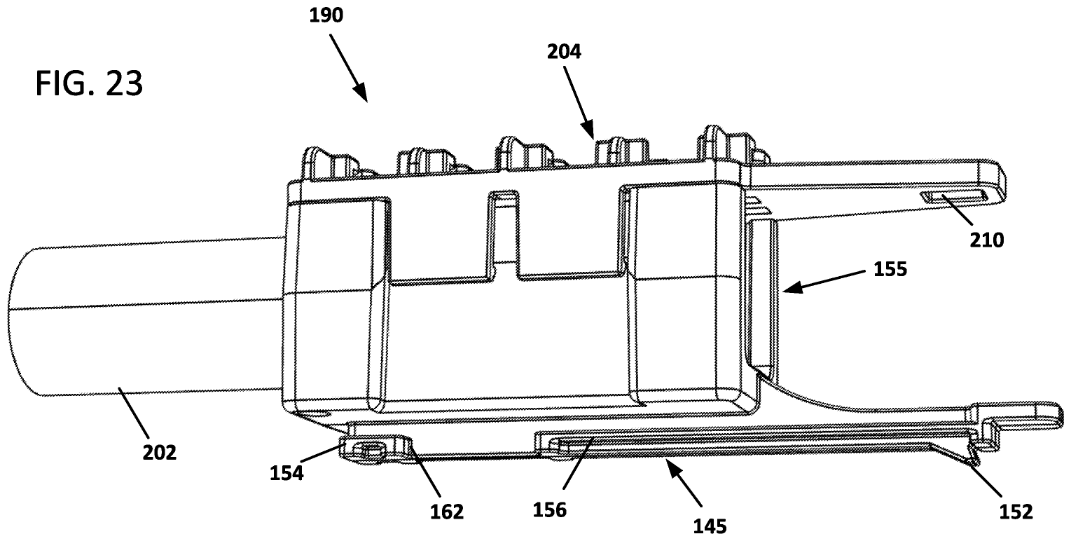

Referring to FIGS. 21-26, the cable mounting structure 155 of a second type of cable anchor 190 is shown. The anchor mounting structure 145 of the second type of cable anchor 190 (e.g., see FIG. 23) is the same as the anchor mounting structure 145 of the first type of cable anchor 140 described above. Accordingly, the cable anchor 190 can be mounted and released from the support plate 110 along either the first path or the second path as described above with reference to FIGS. 11-17.

The cable mounting structure 155 is configured to retain ribbon cables at a furcation region of the cable. At the furcation region, the fiber ribbons are separated into furcation cables with each furcation cable receiving one or more fiber ribbons. The cable mounting structure 155 of the second cable anchor 190 includes a first housing piece 192 defining a cavity 194 that can be closed by a second housing piece 196. The first and second housing pieces 192, 196 cooperate to define the base 146 of the cable anchor 190. The cavity 194 extends along the length L of the cable anchor 190 between a first open end 198 of the first housing piece 192 and a second open end 200 of the first housing piece 192.

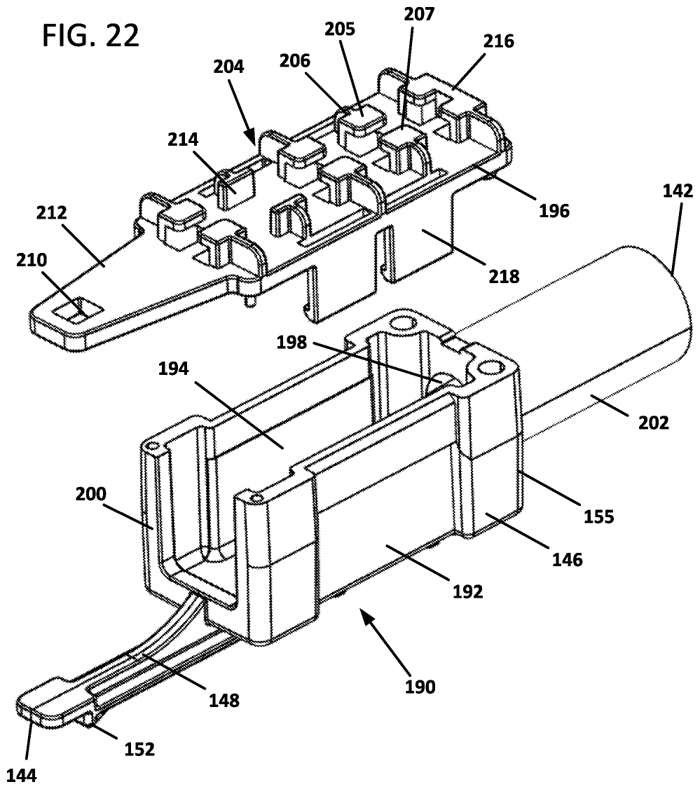

In some implementations, the first and second housing pieces 192, 196 are configured to latch together. In the depicted example, the second housing piece 196 includes one or more latch arms 218 (see FIG. 22) that snap over catch surfaces defined by the first housing piece 192 (e.g., see FIG. 23). In other examples, the first housing piece 192 may include latch fingers and the second housing piece 196 may define catch surfaces. In other examples, both the first and second housing pieces 192, 196 may each define one or more latch arms 218 and one or more catch surfaces. In other implementations, the first and second housing pieces can be otherwise coupled (e.g., welded, fastened, adhesively fixed, friction fit, etc.).

A sleeve 202 extends outwardly from the first open end 198 of the first housing piece 192 to define a cable passage aligned with the cavity 194. The sleeve 202 defines the first end 142 of the cable anchor 190. The sleeve 202 is sized to receive a ribbon cable. In certain examples, the sleeve 202 is sized to receive a jacketed portion of the ribbon cable. At least the fiber ribbons of the ribbon cable extend through the first open end 198 and into the cavity 194. The ribbons are routed into furcation tubes having first ends disposed in the cavity 194. In certain examples, the furcation tubes can be held by a comb or other tube manager disposed within the cavity 194. In certain examples, epoxy or other adhesive can be injected into the cavity 194 to axially retain the ribbon cable and/or the furcation tubes relative to the base 146.

Examples of various types of tube managers and other components of the cable mounting structure 155 of the second type of cable anchor 190 are shown and described in U.S. application Ser. No. 17/044,024, filed Sep. 30, 2020, titled “Cable Fan-out Arrangements and Methods Therefore,” the disclosure of which is hereby incorporated herein by reference in its entirety.

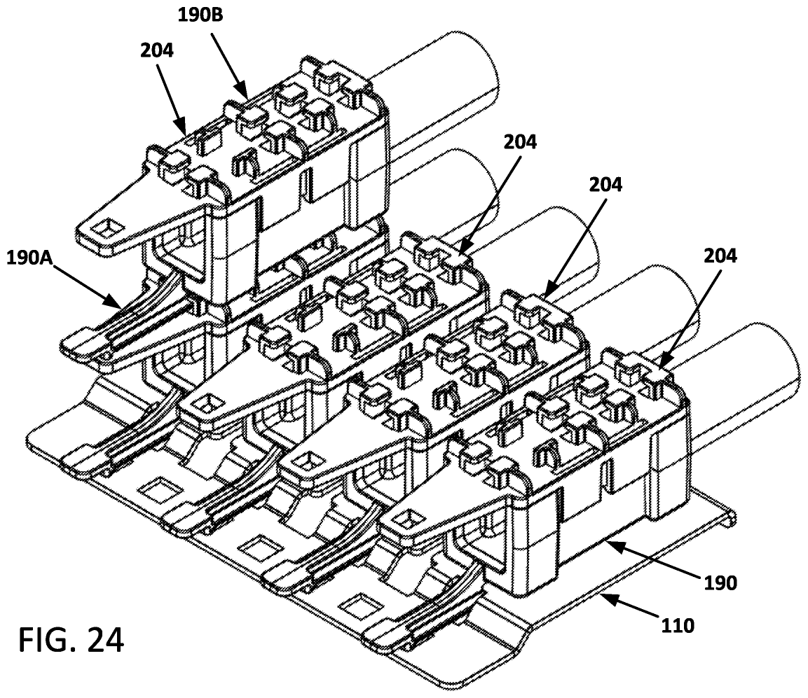

In certain implementations, the second type of cable anchor 190 is configured to be stackable at a cable anchor station 112 (e.g., see FIG. 24). In certain examples, the second housing piece 196 has a first side facing the cavity 194 and an opposite second side facing away from the cavity 194. At the second side, the second housing piece 196 includes a retention arrangement 204 mimicking the structure of the support plate 110 so that the anchor mounting structure 145 of a cable anchor 140, 190, 240 can be mounted to the retention arrangement 204.

As shown in FIG. 21, the retention arrangement 204 includes pairs of opposing fingers 206 aligned along the length L of the cable anchor 190 to define a channel 208 extending along the length L. Certain fingers 206 define a flange 205 extending towards the opposing finger 206 of the pair (e.g., see FIG. 22). The flanges 205 mimic the top and bottom surfaces 121, 123 of the support plate 110. The gap 207 between the flanges 205 mimics the slot 114 of the cable anchor station 112. In certain examples, the retention arrangement 204 includes a pair of tabs 214 disposed among the pairs of fingers 206. The tabs 214 mimic the second enlarged section 118 of the support plate 110. The second housing piece 196 also includes an extension 212 extending away from the fingers 206 towards the second end 144 of the cable anchor 190. The extension 212 defines an aperture 210 positioned the same distance from the fingers 206 as the aperture 120 of the support plate 110 is positioned from the respective slot 114.

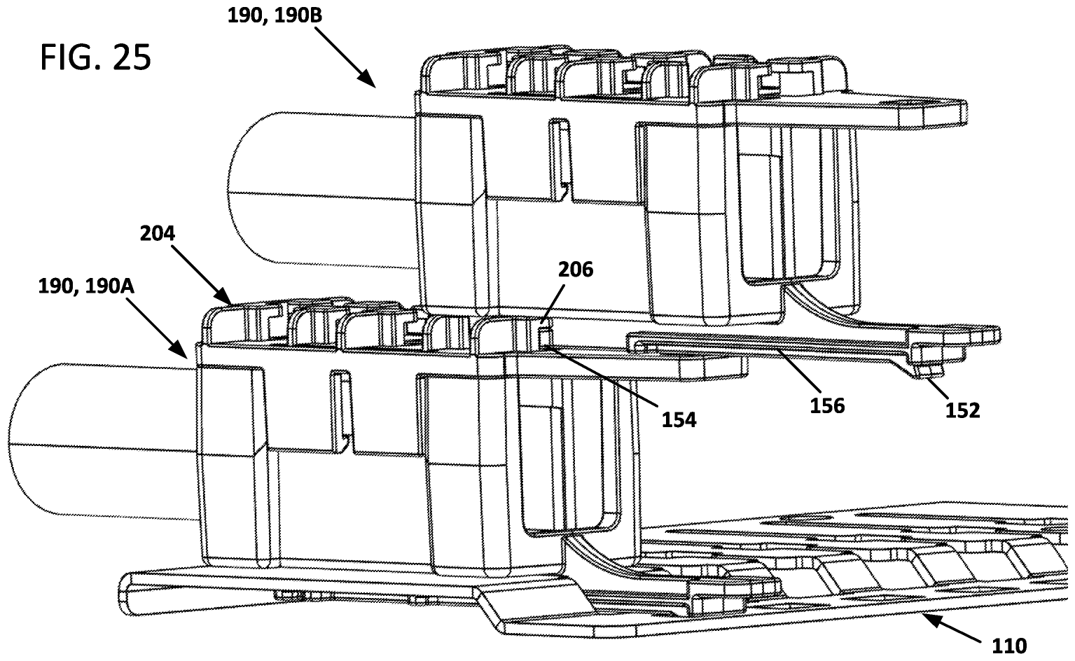

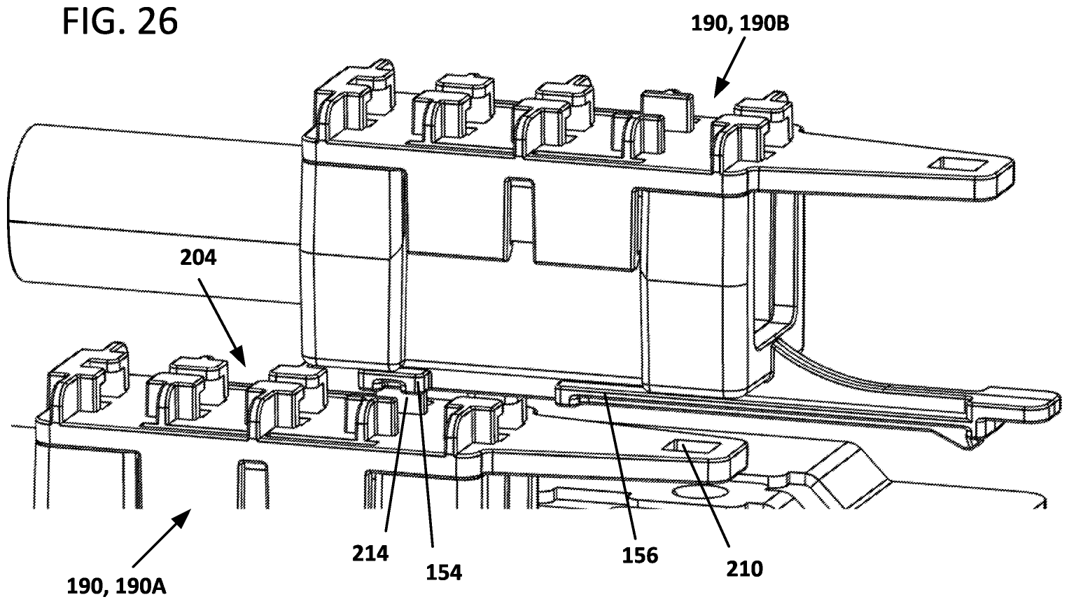

As shown in FIG. 24, a first cable anchor 190A can be mounted to the support plate 110 at a cable anchor station 112 and a second cable anchor 190B can be mounted to retention arrangement 204 of the first cable anchor 190A. Accordingly, both cable anchors 190A, 190B are mounted at the cable anchor station 112 (or at the same location on the support plate 110). As shown in FIGS. 25 and 26, the second cable anchor 190B can be mounted to the retention arrangement 204 of the first cable anchor 190A along either the first path or the second path.

In FIG. 25, the first set of rails 154 of the second cable anchor 190B is aligned with the first pair of fingers 206 of the first cable anchor 190A. The second cable anchor 190B can be slid along the channel 208 defined by the gaps 207 between the finger flanges 205 as the second set of rails 156 pass under the flanges 205 of the first set of fingers 206. The second cable anchor 190B is slid along the channel 208 until the base 146 abuts an end wall 216 of the retention arrangement 204 and the latching member 152 snaps into the aperture 210 in the extension 212. The fingers 206 inhibit upward movement of the second cable anchor 190B relative to the first cable anchor 190A. The end wall 216 and the latching member 152 inhibit axial movement of the second cable anchor relative to the first cable anchor 190A. Thereby, the second cable anchor 190B is mounted to the first cable anchor 190A along the first path.

In FIG. 26, the first set of rails 154 are aligned above the tabs 214 of the retention arrangement 204. The first set of rails 154 can be lowered between the tabs 214 to dispose the first and second sets of rails 154, 156 below the flanges 205 of the fingers 206. The second cable anchor 190B can then be slid along the channel 208 of the retention arrangement 204 as described above until the latching member 152 snaps into the aperture 210. Thereby, the second cable anchor 190B is mounted to the first cable anchor 190A along the second path.

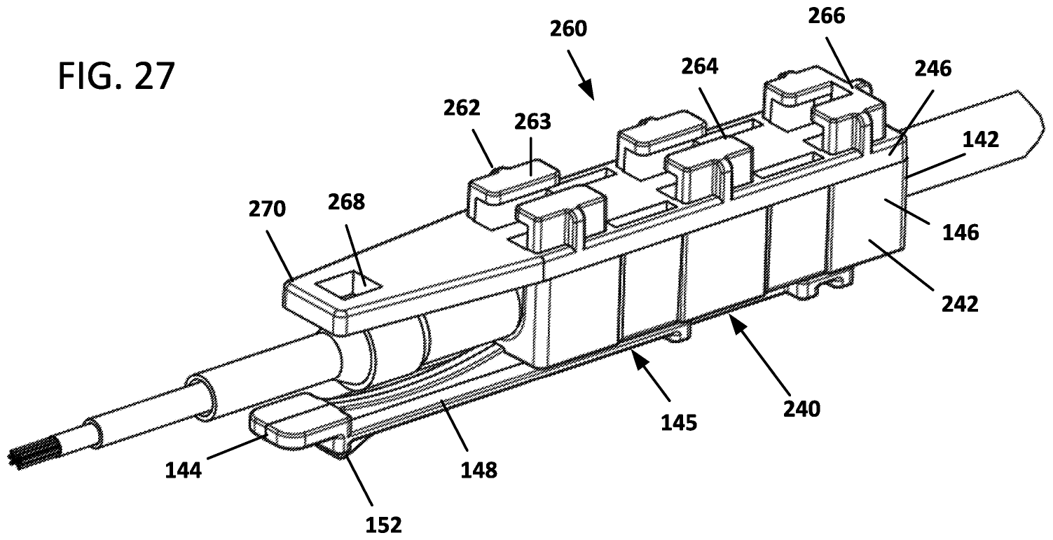

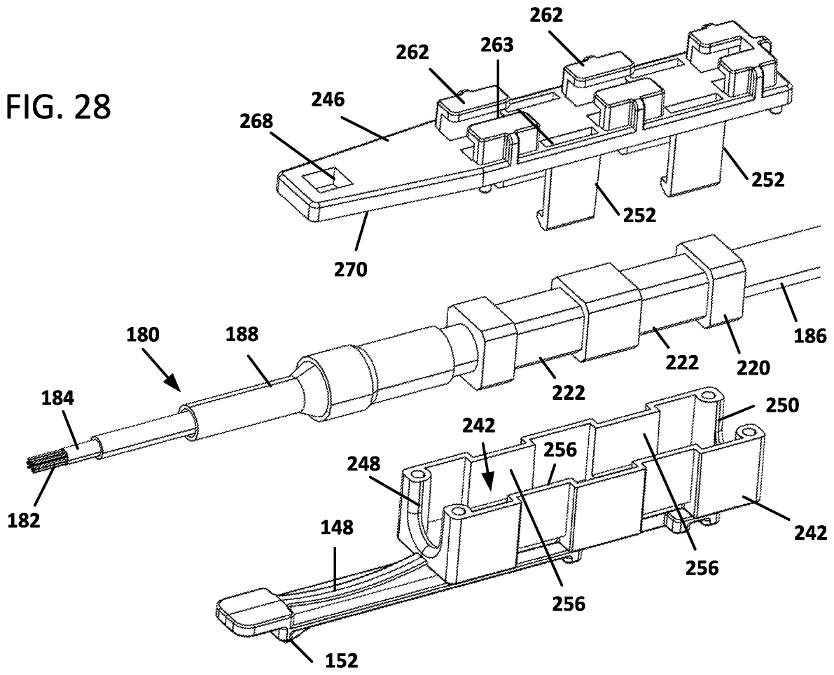

Referring to FIGS. 27-31, the cable mounting structure 155 of a third type of cable anchor 240 is shown. The anchor mounting structure 145 of the third type of cable anchor 240 (e.g., see FIG. 28) is the same as the anchor mounting structure 145 of the first type of cable anchor 140 described above. Accordingly, the cable anchor 240 can be mounted and released from the support plate 110 along either the first path or the second path as described above with reference to FIGS. 11-17.

The cable mounting structure 155 of the cable anchor 240 is configured to retain a portion of a cable 180. In particular, the cable mounting structure 155 is configured to retain an overmolded portion of the cable 180. The overmold 220 is applied over the jacket 186 of the cable 180. In certain examples, the overmold 220 is applied over the jacket 186 at a location spaced from a terminated end of the jacket 186 at which one or more loose tubes 184 extend outwardly from the jacket 186. In certain examples, the overmold 220 is spaced away from a shape-recoverable sleeve 188 covering the transition from the jacket 186 to the loose tube(s) 184. The overmold 220 defines one or more depressions 222 or other contoured sections.

The cable mounting structure 155 of the third cable anchor 240 includes a first housing piece 242 defining an interior 244 that can be closed by a second housing piece 246. The first and second housing pieces 242, 246 cooperate to define the base 146 of the cable anchor 240. The cavity 244 extends along the length L of the cable anchor 240 between a first open end 248 of the first housing piece 242 and a second open end 250 of the first housing piece 242.

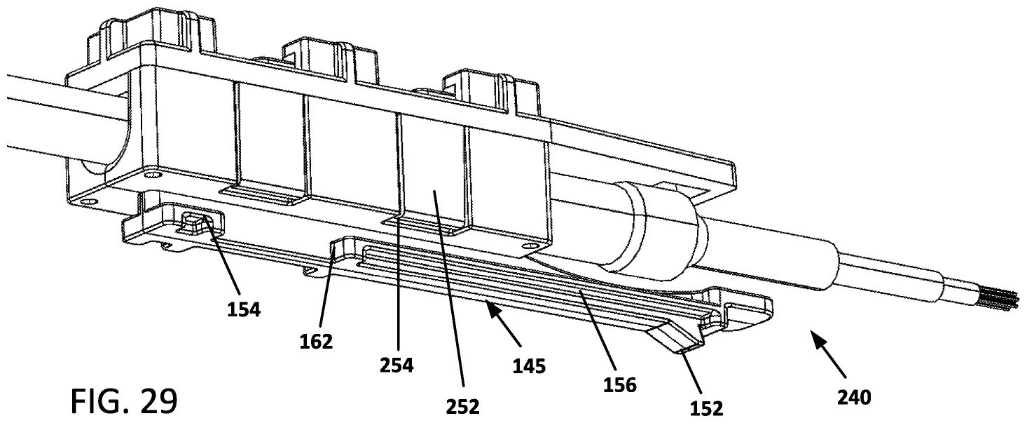

In some implementations, the first and second housing pieces 242, 246 are configured to latch together. In the depicted example, the second housing piece 246 includes one or more latch arms 252 (see FIG. 28) that snap over catch surfaces 254 defined by the first housing piece 242 (e.g., see FIG. 29). In other examples, the first housing piece 242 may include latch fingers and the second housing piece 246 may define catch surfaces. In other examples, both the first and second housing pieces 242, 246 may each define one or more latch arms 252 and one or more catch surfaces 254. In other implementations, the first and second housing pieces 242, 246 can be otherwise coupled (e.g., welded, fastened, adhesively fixed, friction fit, etc.).

As shown in FIG. 28, the interior 244 of the first housing piece 242 is structured to engage the overmold 220 to axially retain the cable 180 relative to the cable anchor 240. In certain examples, the interior 244 includes protrusions 256 that engage the depressions 222. In other examples, the overmold 220 may define one or more protrusions and the first housing piece 242 may define one or more depressions. In certain examples, the engagement between the first housing piece 242 and the overmold 220 inhibits rotational movement of the cable relative to the cable anchor 240.

In certain implementations, the third type of cable anchor 240 is configured to be stackable at a cable anchor station 112 (e.g., see FIG. 24). In certain examples, the second housing piece 246 has a first side facing the cavity 244 and an opposite second side facing away from the cavity 244 At the second side, the second housing piece 246 includes a retention arrangement 260 mimicking the structure of the support plate 110 so that the anchor mounting structure 145 of a cable anchor 140, 190, 240 can be mounted to the retention arrangement 260.

As shown in FIG. 27, the retention arrangement 260 includes pairs of opposing fingers 262 aligned along the length L of the cable anchor 240 to define a channel 264 extending along the length L. The fingers 262 define flange 263 extending towards the opposing finger 262 of the pair (e.g., see FIG. 27). The flanges 263 mimic the top and bottom surfaces 121, 123 of the support plate 110. The channel 264 between the flanges 263 mimics the slot 114 of the cable anchor station 112. The fingers 262 are axially spaced from each other along the length. In certain examples, the axial spacing between the fingers 262 is at least as long as the length L1 of the first set of rails 154 of the anchor mounting structure 145. The second housing piece 246 also includes an extension 270 extending away from the fingers 262 towards the second end 144 of the cable anchor 240. The extension 270 defines an aperture 268 positioned the same distance from the fingers 262 that the aperture 120 of the support plate 110 is positioned from the respective slot 114.

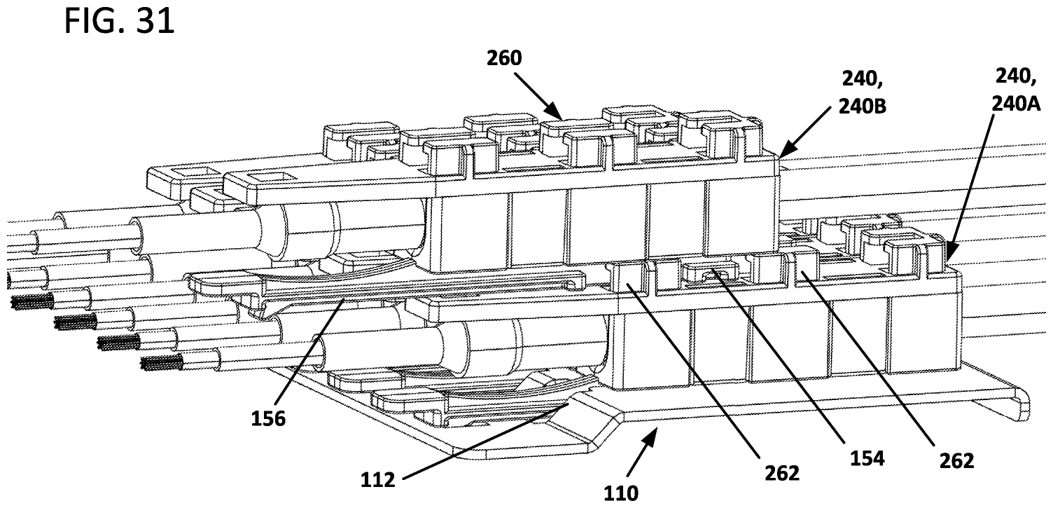

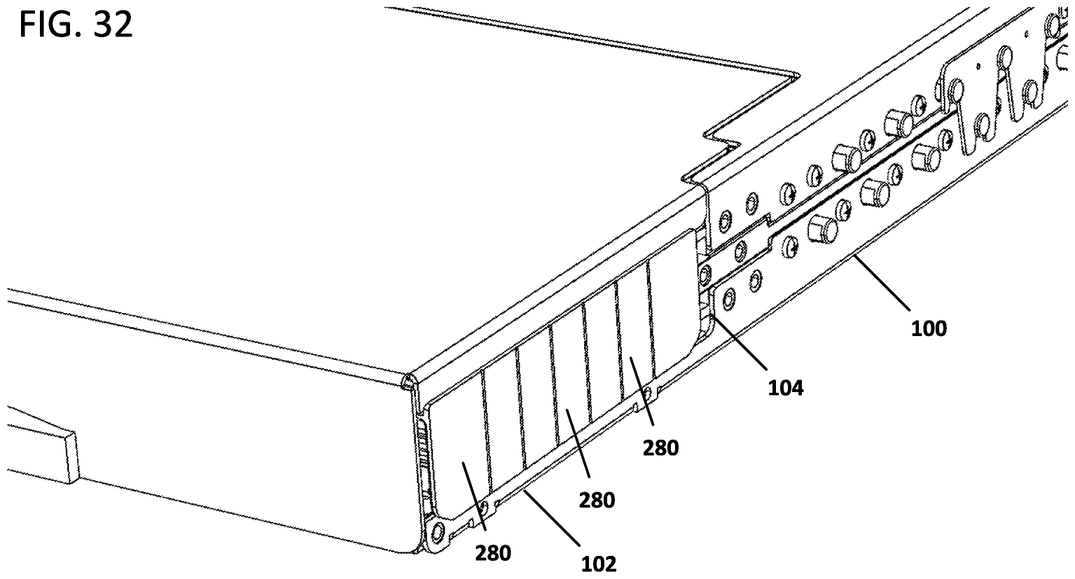

As shown in FIG. 31, a first cable anchor 240A can be mounted to the support plate 110 at a cable anchor station 112 and a second cable anchor 240B can be mounted to retention arrangement 260 of the first cable anchor 240. Accordingly, both cable anchors 240A, 240B can be mounted at the cable anchor station 112 (or at the same location on the support plate 110). In certain examples, the second cable anchor 240B can be mounted to the retention arrangement 260 of the first cable anchor 240A along either the first path or the second path. To mount along the first path, the first set of rails 154 of the top-side cable anchor 240B slide beneath the flanges 263 of all of the fingers 262 towards an end wall 266 of the retention arrangement 260. To mount along the second path, the first set of rails 154 are dropped into the axial spacing between the fingers 262 (e.g., see FIG. 31) and then slid towards the end wall 266.

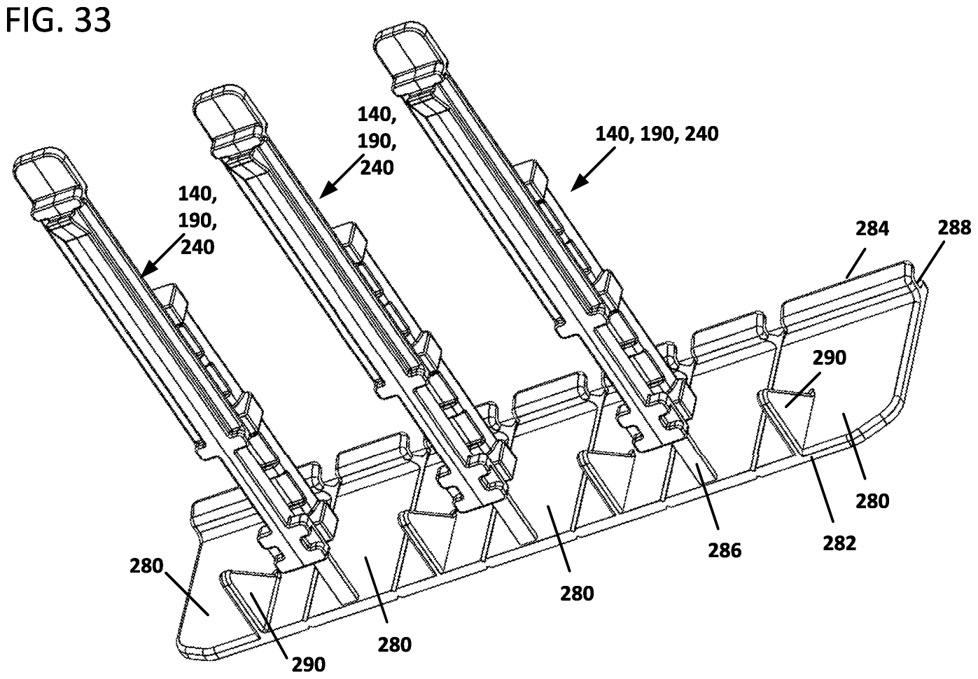

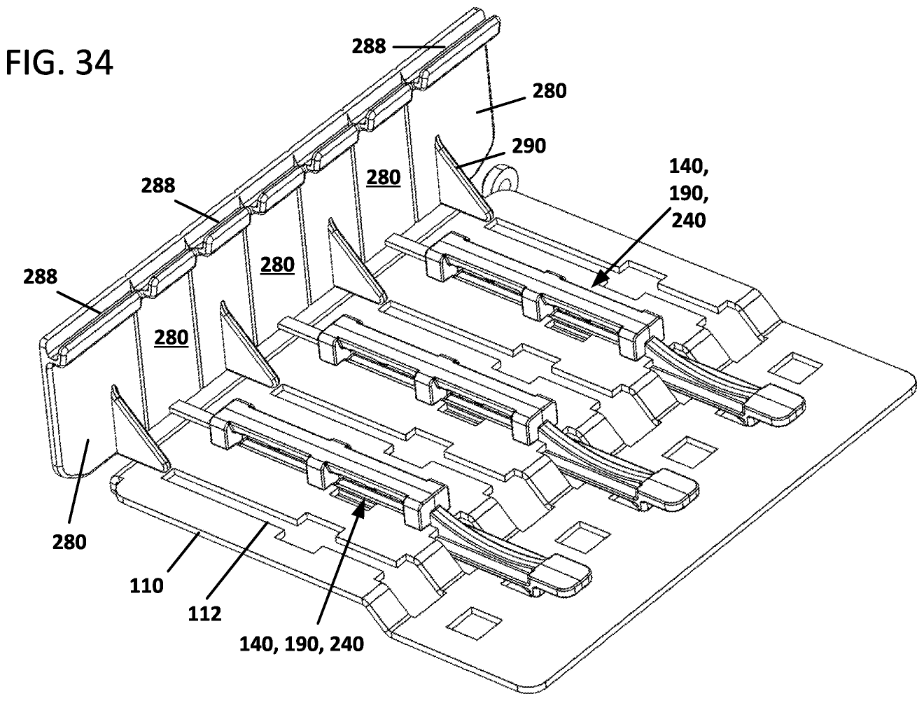

Referring to FIGS. 32-34, the cable anchors 140, 190, 240 can be equipped with a blocker 280 to close an opening at the routing entrance 104 of the management shelf 102 of a chassis 100 (e.g., see FIG. 32). Each blocker 280 extends along a height from a bottom 282 to a top 284. The height of each blockers 280 extends along a height of the routing entrance 104. In certain examples, the top 284 of each blocker 280 defines a channel 288 or other feature configured to interface with the chassis 100 or rear cover of the management shelf 102. In certain examples, each blocker 280 extends along a portion of the length of the routing entrance 104.

In accordance with certain aspects of the disclosure, each blocker 280 is carried by one of the cable anchors 140, 190, 240. For example, a frangible web 286 may extend between the cable anchor 140, 190, 240 and the blocker 280. In the depicted example, the web 286 extends between the first end 142 of the cable anchor 140, 190, 240 and the bottom 282 of the blocker 280. When the cable anchor 140, 190, 240 is needed for use, the blocker 280 is removed from the cable anchor (e.g., by breaking the web 286) to provide a space through which the cable (e.g., cable 180) can be routed to the support plate 110 through the routing entrance 104.

In some implementations, each cable anchor 140, 190, 240 carries more than one blocker 280. In the depicted example, a second blocker 280 is removably attached to a side edge of a first blocker 280 that is attached to a cable anchor 140, 190, 240. Such side blockers 280 may include stabilizers 290. Removing the second blocker 280 provides an opening through the routing entrance 104 while the first blocker 280 continues to block another portion of the routing entrance 104. In other implementations, each blocker 280 is carried by a respective cable anchor 140, 190, 240.

In still other implementations, the blockers 280 may be mounted at the routing entrance 104 separate from the cable anchors 140, 190, 240.

Having described the preferred aspects and implementations of the present disclosure, modifications and equivalents of the disclosed concepts may readily occur to one skilled in the art. However, it is intended that such modifications and equivalents be included within the scope of the claims which are appended hereto.

What is claimed is:

1. A cable anchor system comprising:
a cable anchor having a length that extends between opposite first and second ends of the cable anchor, the cable anchor including a base and an arm extending outwardly from the base to define the second end of the cable anchor, the base defining a support surface facing in a first direction, the arm being deflectable relative to the base and carrying a latch member extending in a second direction opposite the first direction, the cable anchor also including a first set of guide rails that extend along a first portion of the length of the cable anchor at opposite sides of the cable anchor and a second set of guide rails that extend along a second portion of the length of the cable anchor at opposite sides of the cable anchor, the guide rails of the second set being longer than the guide rails of the first set, the second set of guide rails being spaced from the first set of guide rails along a third portion of the length of the cable anchor.

2. The cable anchor system of claim 1, wherein the base includes sidewalls extending upwardly from the support surface to define an interior accessible through an open top, an aperture at a first end of the base and an aperture at an opposite second end of the base, and wherein the cable anchor includes a cover that mounts to the base to enclose the interior.

3. The cable anchor system of claim 2, wherein the cable anchor is a first cable anchor; and wherein the cover defines a mounting structure at an opposite side of the cover from the interior, the mounting structure being mateable with a base of a second cable anchor that is identical to the first cable anchor.

4. The cable anchor system of claim 2, further comprising a cable having a retention member disposed over a jacket of the cable, the retention member being shaped to engage with a retaining structure within the interior to inhibit movement of the cable relative to the cable anchor along the length of the cable anchor.

5. The cable anchor system of claim 2, wherein the cable anchor includes a sleeve extending outwardly from the first end of the base, the sleeve defining a passageway leading to the interior through the aperture at the second end of the base.

6. The cable anchor system of claim 1, wherein the base defines a passage extending transverse to the length of the cable anchor, the passage defined beneath the support surface and above the first and second sets of guide rails.

7. The cable anchor system of claim 6, wherein the passage is one of a plurality of passages extending transverse to the length of the cable anchor.

8. The cable anchor system of claim 6, further comprising a cable and a wrap-style fastener, the cable extending over the support surface, the wrap-style fastener extending through the passage, wrapping around the cable, and fastening together to hold the cable to the cable anchor.

9. The cable anchor system of claim 8, wherein the cable is one of a plurality of cables mounted to the cable anchor using the wrap-style fastener.

10. The cable anchor system of claim 1, wherein the rails of the second set are at least twice as long as the rails of the first set.

11. The cable anchor system of claim 10, wherein the rails of the second set are at least five times as long as the rails of the first set.

12. The cable anchor system of claim 1, wherein the third portion of the length is larger than the first portion of the length and smaller than the second portion of the length.

13. The cable anchor system of claim 1, further comprising a support plate having a depth extending between opposite first and second ends, a width extending between opposite first and second sides, and a thickness extending between a top and a bottom, the support plate defining a closed-ended slot extending along the depth of the support plate and an aperture aligned with and spaced from the slot along the depth of the support plate, the aperture being sized to receive the latch of the deflectable arm.

14. The cable anchor system of claim 13, wherein the slot defines first and second spaced apart enlarged sections spanning a common distance along the depth of the support plate, the common distance being no longer than the first portion of the length of the cable anchor.

15. The cable anchor system of claim 14, wherein the support plate has a first region defining the first end, a second region defining the second end, and a transition region extending between the first and second regions, the transition region being contoured so that the second region is raised along a height relative to the first region, the height extending in parallel with the thickness of the support plate.

16. The cable anchor system of claim 15, wherein the first enlarged section is disposed at the first region, the second enlarged section is disposed at the transition region so that the second enlarged section is angled along the height relative to the first enlarged section, and the aperture is disposed at the second region.

17. A method of mounting a cable anchor to a support plate comprising:
passing a first end of the cable anchor through an enlarged section of a slot defined in the support plate so that a first pair of rails move from above the support plate, through the enlarged section, to beneath the support plate while a second set of rails remains above the support plate;
sliding the cable anchor along the slot in a first direction until a portion of a second pair of rails moves from above the support plate to beneath the support plate; and
latching the cable anchor to the support plate to inhibit movement in a second direction that is opposite the first direction.

18. The method of claim 17, wherein the second pair of rails moves from above the support plate to beneath the support plate through the enlarged section.

19. The method of claim 18, wherein the cable anchor is fully mounted to the support plate without pivoting the cable anchor.

20. The method of claim 17, wherein the second pair of rails moves from above the support plate to beneath the support plate through another enlarged section of the slot that is spaced along the slot from the enlarged section.

21. The method of claim 20, further comprising pivoting the cable anchor relative to the support plate to align the second pair of rails with the another enlarged section prior to sliding the cable anchor along the slot in a first direction until a portion of a second pair of rails moves from above the support plate to beneath the support plate.
